(19) United States
(12) Patent Application Publication
(10) Pub. No.: US 2017/0084817 A1
(43) Pub. Date: Mar. 23, 2017

(54) Piezoelectric Power Generating Tire Apparatus

(71) Applicants: Gustavo Antonio Navarro, Bowie, MD (US); Carlos Luis Fuentes Rojas, Santiago (CL)

(72) Inventors: Gustavo Antonio Navarro, Bowie, MD (US); Carlos Luis Fuentes Rojas, Santiago (CL)

(21) Appl. No.: 15/138,153

(22) Filed: Apr. 25, 2016

Related U.S. Application Data
(60) Provisional application No. 62/152,073, filed on Apr. 24, 2015.

(51) Int. Cl. H01L 41/113; H02J 50/10; H01L 41/09; B60C 19/00; H02N 2/18

(52) U.S. Cl. CPC H01L 41/113; B60C 19/00; H02N 2/181; H01L 41/09; H02J 50/10

(57) ABSTRACT

A system and apparatus for generating electricity via at least one piezoelectric cable embedded within the tires of a vehicle is described. Electricity is converted from pressure exerted by the weight of the car compressing on the outer circumference of the tires as the tire rotates. The electricity is converted via the piezoelectric cable, and is then conveyed by induction to reinforce and supplement the electrical systems of the vehicle. The apparatus is configured as a complete circuit, facilitating the use of current within the circuit to harden or soften the piezoelectric cable, and therefore stiffen or soften the overall ride of the tires equipped with the apparatus.

### CONTINUITY

This application is a non-provisional application of provisional patent application No. 62/152,073, filed on Apr. 24, 2016, and priority is claimed thereto.

### FIELD OF THE PRESENT INVENTION

The field of the present invention relates to mobile methods of power generation, and more specifically, the present invention relates to the conversion of kinetic energy to electricity from the compression of a vehicle's tires, transmitted to vehicle systems via induction.

### BACKGROUND OF THE PRESENT INVENTION

A variety of measures have been taken to minimize the power consumption of modern electric and hybrid vehicles in order to maximize their range between charges. From an aerodynamic design, to regenerative braking mechanics, manufacturers are creating new ways to harness and reuse the energy lost within a moving vehicle. One of the primary pitfalls of electric vehicles is their limited distance and travel time. Charging the batteries between uses takes time, which is not always abundant. Exchanging batteries easily at home remains an unavailable option. Fuel cell technology is still in its infancy. Therefore, many vehicle manufacturers are looking for new ways to add charge to the batteries, helping to extend the possible distance the vehicle can travel before running out of power.

Unfortunately, many of the methods of power generation in a moving vehicle would add more weight and drag to the vehicle when implemented than the net energy output of such a system, making most of these ‘energy saving’ endeavors unviable. While the concept of perpetual motion has been long disproven, it remains possible to regain some of the power lost to heat and friction within the system of a motor vehicle.

The majority of energy that is lost with a combustion engine is conventionally within the combustion of the fuel itself. With any vehicle, however, many factors cause unnecessary power loss. Much of this power sacrifice is due to friction. Vehicle tires are designed to provide a comfortable ride, to ensure sufficient braking power with adequate traction on multiple surfaces, and to minimize damage to the road surface during use. A softer, larger tire yields a more comfortable ride, minimizing damage to the road surface. As such, conventional tires are usually safe on a wide variety of surfaces. Unfortunately, mileage, and ultimately power consumption, is inversely proportional to tire hardness. Additionally, firm or solid-state tires would cause undue damage to the road surface, and yield an uncomfortable ride on open roadways. Per regulations, tires must be of a certain caliber to be considered street legal, for the sake of safety. Therefore, tires conventionally made today are configured to compress as they rotate, contributing to additional power loss, due to a less energy efficient wheel system.

Drag from the profile of the vehicle may also decrease the efficiency of the power system of a vehicle. Efforts have been taken to lower the profile of motor vehicles in an effort to minimize wind resistance. While this has had success, there is not at present a method to recapture energy lost from drag.

Thus, there is a need for an apparatus configured to harness and employ power captured via the compression of the rubber tires of a motor vehicle. Such a system would preferably be crafted to convey an electric current generated from the very compression of the tires of the vehicle to the electrical system of the vehicle. As such, the harnessed power can be employed to recharge batteries and supplement the electrical systems of the vehicle. The current would preferably be conveyed from the frictional compression of the tires via a piezoelectric cable interfaced with a wireless inductive coupler configured to transmit the current from the rotating tire and rim assembly to the brake assembly, and ultimately to the electrical systems of the vehicle.

### SUMMARY OF THE PRESENT INVENTION

The present invention is a piezoelectric power generating system that conveys electricity from power generated by the compression of the tires of a vehicle outfitted with piezoelectric cabling integrated into the tires. Given that the wheel is spinning as power is generated, the electricity is conveyed via induction across to the rotor assembly, where it may be used within the vehicle. Preferably, at least one conventional Piezo-Polymer coaxial cable is integrated with, or affixed to, the interior of the conventional vehicle tire, and is wired in a continuous circuit.

As the tires rotate, the weight of the vehicle is applied to a constantly rotating tire surface, causing the tire to compress when in contact with the ground several times per second. The piezo-polymer cable of the present invention is similarly compressed as the tire rotates, generating a small, yet consistent electric current. The current is conveyed via induction to a capacitor to await use as a power source for the electrical systems of the vehicle.

Currently, few products are available that attempt to harness power lost within the wheel systems of modern vehicles. In 2015, Goodyear™ announced a prototype design purporting to harness the heat from power loss due to friction of the vehicle's tires against the road surface, brake pad surface, or other surfaces. The proposed system employed a cooling system, which was needed to safely employ the system. While the system proposed by Goodyear™ does capture power from a rotating tire, it fails to capture it from the compression of the tire itself. As such, the concept proposed by Goodyear™ does not employ a piezoelectric cable to generate a current, nor is the current generated conveyed via induction, unlike the present invention.

### BRIEF DESCRIPTION OF THE DRAWINGS

The present invention will be better understood with reference to the appended drawing sheets, wherein:

FIG. 1 displays a view of the preferred embodiment of the present invention as seen from the side, integrated into the exterior circumference of a motor vehicle tire.

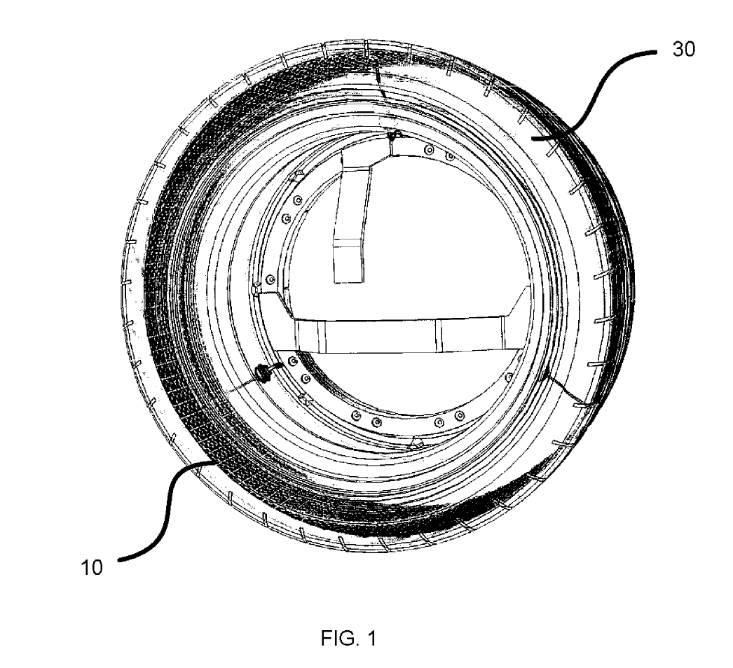

FIG. 2 displays an example layout of the piezoelectric lining to be disposed within the tire, preferably on the exterior of the tube of the tire.

FIG. 3 exhibits solely the primary components of the present invention, isolated from the tire.

### DETAILED DESCRIPTION OF THE PREFERRED EMBODIMENT

The present invention comprises a system to facilitate the conversion of kinetic energy via compression into electricity within a conventional tire. The present invention is equipped with a piezoelectric bank (10) consisting of at least one piezoelectric cable (20) that is disposed within a tire (30) of a vehicle. The at least one piezoelectric cable (20) is preferably integrated into the rubber tube lining of a conventional tire tube, or affixed to the exterior circumference of the tube encased within the tire. The system of the present invention is equipped with a wireless inductive coupler (40) and a wireless transmitter (50) to facilitate the transfer of current via induction. The wireless inductive coupler (40) is preferably ferrite shielded.

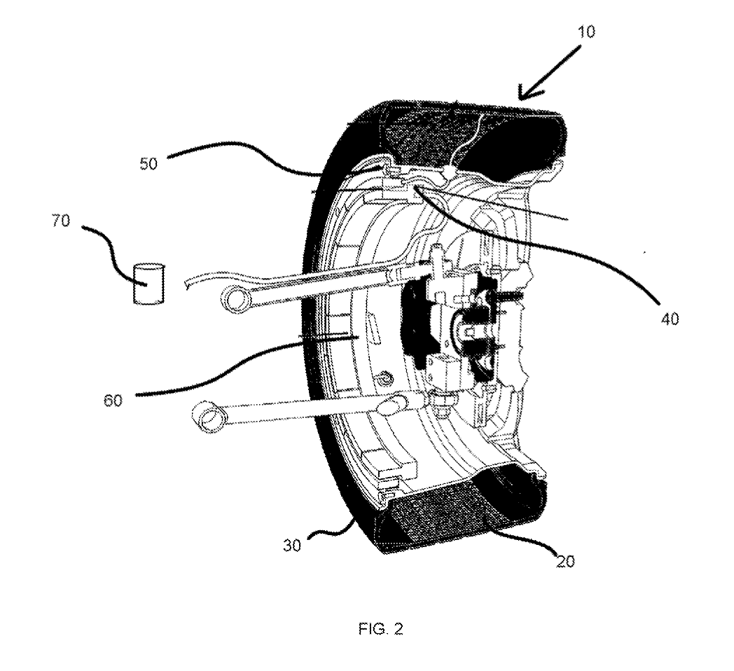

The piezoelectric bank (10) and the wireless transmitter (50) of the preferred embodiment of the present invention are disposed on the wheel and rim assembly itself, and are therefore subject to dynamic rotation when the vehicle is in motion. A wireless receiver (60), integrated into the wireless inductive coupler (40) in configured to interface with the wireless transmitter (50) as it is disposed in close proximity to the wireless transmitter (50) as seen in FIG. 2. At least one capacitor (70) is employed by the system of the present invention to store the power load generated when the system is in use. The at least one capacitor (70) is preferably disposed on the non-rotating portion of the present invention, either within or near the wireless inductive coupler (40), or within the chassis of the vehicle, closer to the vehicle's systems.

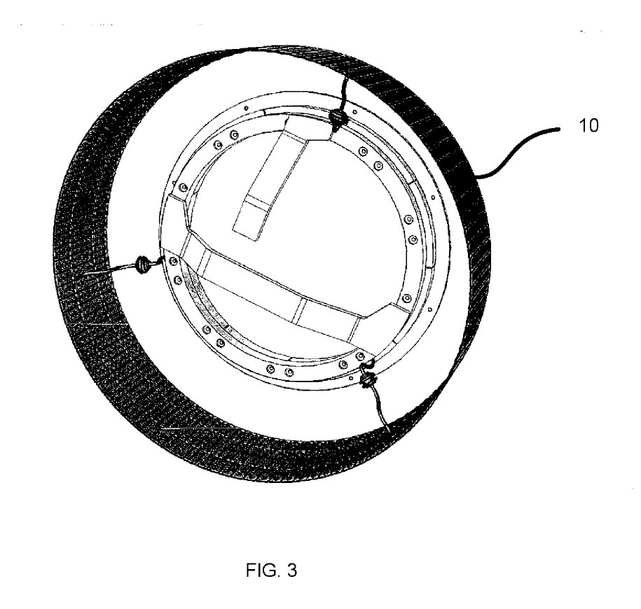

The at least one piezoelectric cable (20) of the present invention is preferably disposed in an organized tread pattern, similar to that seen in FIG. 3. It should be noted that this is a merely an example layout of one embodiment of the present invention, and that the system of the present invention in no way requires the placement of the at least one piezoelectric cable (20) at such a disposition. However, in all embodiments of the present invention, the at least one piezoelectric cable (20) is centered and aligned within the tire (30), preferably between the tube and the tire (30), or integrated into the rubber polymer of the tire (30) itself. As such, the system of the present invention does not affect the calibration or spin of the tires, and are balanced accordingly.

It should be understood that the present invention need not be limited to use on motor vehicles, but may be employed on any wheel. For example, some embodiments of the present invention may be configured to integrate the at least one piezoelectric cable (20) into a bicycle tire of a bicycle, facilitating the generation of power to be employed to power the headlight of the bicycle, on-board trip computer of the bicycle, or charge the rider's mobile device.

Further, it should be understood that the at least one piezoelectric cable (20) of the present invention may be a form of piezoelectric-thermoelectric film. As such, power from heat within the piezoelectric-thermoelectric film may also be used in power generation. Additionally, it should be understood that the present invention may be outfitted for use on airless tires, which employ semi-rigid spokes which are partially contorted as the tires rotate. In such instances, the at least one piezoelectric cable (20) of the present invention may be disposed within the semi-rigid spokes to efficiently generate and capture power for use within the electrical systems of the vehicle.

Alternate embodiments of the present invention may include variations on the format of the piezoelectric bank (10) of the present invention, such that the arrangement of the at least one piezoelectric cable (20) is tailored to the tire size and shape used on the vehicle. For example, one embodiment of the present invention is configured to be integrated into the wheel system of electrical industrial equipment, including but not limited to, forklifts, pullers, towers, mining equipment, draglines, earth movers, and other heavy equipment. The system of the present invention can be adapted for industrial or heavy equipment that employs a combustion engine, however the reclaimed power captured by the present invention would be employed to charge onboard batteries, and/or power accessory electrical systems.

It should be known that the tension or rigidity of conventional piezoelectric cabling is variable when a current is supplied to the circuit. As such, a tire (30) equipped with the system of the present invention can be customized by the user with respect to the road surface type or condition in use. For example, a cabin control panel in communication with the at least one piezoelectric cable (20) of the present invention can supply additional current to the circuit of the system of the present invention, effectively causing the outer surface of the tire (30) to harden, yielding better fuel mileage on solid, smoothly paved roads. Conversely, the driver may opt to decrease the current flowing through the circuit of the present invention, causing the outer surface of the tire (30) to soften, facilitating a smoother drive on bumpy roads, while also sacrificing fuel mileage.

Other alternate embodiments of the present invention include the implementation and positioning of the piezoelectric bank (10) on an Airless tire, disposed along the compressible spokes of such a tire. In such a case, the force of the compression of the entirety of the tire itself as the vehicle travels, is conveyed to the at least one piezoelectric cable (20), generating power.

Having illustrated the present invention, it should be understood that various adjustments and versions might be implemented without venturing away from the essence of the present invention. Further, it should be understood that the present invention is not solely limited to the invention as described in the embodiments above, but further comprises any and all embodiments within the scope of this application.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The exemplary embodiment was chosen and described in order to best explain the principles of the present invention and its practical application, to thereby enable others skilled in the art to best utilize the present invention and various embodiments with various modifications as are suited to the particular use contemplated.

I claim:

1. A vehicle power recovery apparatus comprising:
a tire, said tire equipped with rubber lining;
at least one piezoelectric cable, said at least one piezoelectric cable integrated into said rubber tube lining of said tire;
a wireless inductive coupler, said wireless inductive coupler equipped with a wireless receiver;
at least one capacitor, said at least one capacitor disposed within said wireless inductive coupler;
wherein said at least one capacitor is configured to store electricity generated via said at least one piezoelectric cable;
a wireless receiver, said wireless receiver disposed adjacent to a rotor assembly of the vehicle;
a wireless transmitter, said wireless transmitter in communication with said wireless receiver;
wherein said wireless transmitter is in direct communication with said wireless inductive coupler;
a piezoelectric bank, said piezoelectric bank in communication with said at least one piezoelectric cable; and
wherein said piezoelectric bank is configured to convey electricity from said at least one piezoelectric cable to said at least one capacitor via induction across said wireless inductive coupler.

2. The apparatus of claim 1, wherein said at least one piezoelectric cable is aligned such that it is centered within the tire, disposed between a tube of said tire and said rubber lining of said tire.

3. The apparatus of claim 1, wherein the supply of current to said at least one piezoelectric cable is adjustable from within a cabin of the vehicle.

4. The apparatus of claim 1, wherein said wireless inductive coupler is ferrite shielded.

5. The apparatus of claim 1, wherein the supply of current to said at least one piezoelectric cable is increased via a battery of the vehicle to harden said at least one piezoelectric cable.

6. The apparatus of claim 2, wherein the supply of current to said at least one piezoelectric cable is adjustable from within a cabin of the vehicle.

7. The apparatus of claim 2, wherein said wireless inductive coupler is ferrite shielded.

8. The apparatus of claim 2, wherein the supply of current to said at least one piezoelectric cable is increased via a battery of the vehicle to harden said at least one piezoelectric cable.

9. A method for generating electricity via the compression of vehicle tires comprising:
embedding at least one piezoelectric cable within a rubber exterior of the vehicle tires;
wiring the at least one piezoelectric cable to an electric system of the vehicle via a wireless inductive coupler, a wireless transmitter, and a wireless receiver;
rolling the vehicle on the vehicle tires;
the weight of the vehicle compressing the vehicle tires during rotational movement;
the weight of the vehicle compressing the at least one piezoelectric cable within the vehicle tires, generating current;
allowing the current to flow from the at least one piezoelectric cable to the wireless transmitter;
conveying the current from the wireless transmitter to the wireless receiver and wireless inductive coupler via induction;
conveying the current to at least one capacitor;
using the current stored in the at least one capacitor for electrical systems of the vehicle.

10. The method of claim 9, further comprising:
charging the battery of the vehicle via the current stored in the at least one capacitor.

11. A method for dynamically adjusting the rigidity of a rubber tire of a vehicle comprising:
embedding at least one piezoelectric cable within a rubber exterior of the vehicle tire;
wiring the at least one piezoelectric cable to an electric system of the vehicle via a wireless inductive coupler, a wireless transmitter, and a wireless receiver;
supplying current from a battery of the vehicle to the at least one piezoelectric cable via the wireless inductive coupler, hardening the at least one piezoelectric cable; and
the supply of current to the at least one piezoelectric cable hardening the rubber exterior of the vehicle tire, increasing gas mileage.

12. The method of claim 11, further comprising:
decreasing the supply of current from the battery of the vehicle to the at leas tone piezoelectric cable via the wireless inductive coupler, softening the at least one piezoelectric cable.
